(19) United States
(12) Patent Application Publication
(10) Pub. No.: US 2006/0046371 A1
(43) Pub. Date: Mar. 2, 2006

(54) Methods of forming gate electrodes in semiconductor devices

(76) Inventor: Jae Yuhn Moon, Chungcheongbuk-do (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/216,716

(22) Filed: Aug. 31, 2005

(30) Foreign Application Priority Data
Sep. 1, 2004 (KR) 10-2004-69512

(51) Int. Cl. H01L 21/8238; H01L 21/302

(52) U.S. Cl. 438/199; 438/692

(57) ABSTRACT

Method for forming gate electrode in semiconductor device are disclosed. In one example, the method may include forming a gate oxide layer on a substrate having a region where a PMOS region and a NMOS region are formed; depositing a polysilicon of rugged structure on the gate oxide layer; planarizing the polysilicon by a CMP (Chemical Mechanical Polishing) process; and performing ions implantation to the PMOS and NMOS regions and then annealing process.

### TECHNICAL FIELD

The present disclosure relates to semiconductor devices and, more particularly to methods of forming gate electrodes in semiconductor devices.

### BACKGROUND

As information media, such as computers, develop the manufacturing technology of a semiconductor device has rapidly developed. The semiconductor device has advanced toward large-scale integration, miniaturization, and higher operational speed. As known by Moore's law, the integration of semiconductor devices has improved about 2 times every 2 years, and the chip size and the design rule have decreased more and more.

As the semiconductor device is miniaturized and highly integrated, the various problems that cause the degradation of the performance and electrical characteristics of the semiconductor device have become especially important. One such problem is boron penetration in a P-Channel Metal Oxide Semiconductor (PMOS) gate. As the integration of the semiconductor device increases, the thickness of a gate oxide layer is thinner (for example, in case of 0.13 μm process technology, the gate oxide layer has a thickness of about 20 Å). As the thickness of the gate oxide layer becomes smaller, the boron penetration may cause fatal problems in the semiconductor device.

The mechanism of the boron penetration is described in detail with reference to FIGS. 1a, 1b, and 1c.

Referring to FIG. 1a, boron ions are implanted to the PMOS region, and phosphorus (P) or arsenic (As) ions are implanted to an N-Channel Metal Oxide Semiconductor (NMOS) region so that source/drain regions 110 are formed. A device isolation layer 102, a gate oxide layer 104, a polysilicon gate 106, and spacers 108 for a Lightly Doped Drain (LDD) structure are formed on a substrate 100. As shown in FIG. 1b, the boron ions gather on the upper area of gate electrode 106 after the boron ions are implanted.

Next, as shown in FIG. 1c, an annealing process is carried out to the source/drain regions 110, and therefore the boron ions diffuse into a lower area of the gate electrode 106. The diffusion of boron is generally made through a grain boundary in the gate electrode 106. As shown at A in FIG. 1c, the boron ions penetrate into the substrate 100 during annealing, which results in the degradation of semiconductor device, because the mobility of boron ions is very high in the conventional polysilicon gate having a columnar structure.

The problem of the boron penetration to the PMOS region may be solved by decreasing the annealing temperature. However, the annealing temperature should be kept high enough to activate the depletion region where the phosphorus (P) or the arsenic (As) ions are doped on the NMOS region. Therefore, the annealing temperature cannot be decreased.

In order to solve the problem, Korean Patent Registration No. 135166 discloses a method for preventing a boron penetration comprising: depositing orderly a polysilicon, an amorphous silicon, and a gate insulating layer; ion-implanting BF₂⁺; and forming a policide by depositing the metal having high melting point. However, the prior method is very complicated, and has limitations in that the polysilicon of the columnar structure is difficult in preventing the boron penetration.

### BRIEF DESCRIPTION OF DRAWINGS

FIGS. 1a, 1b, and 1c are cross-sectional views of a conventional method for forming a gate in semiconductor device.

FIGS. 2a, 2b, and 2c are cross-sectional views for describing an example disclosed method of forming gates in semiconductor devices.

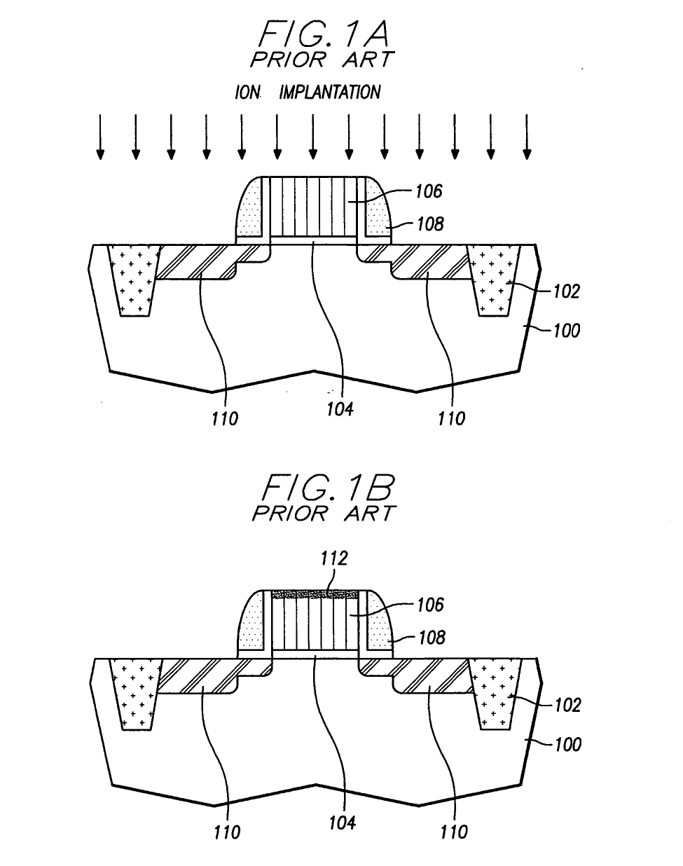

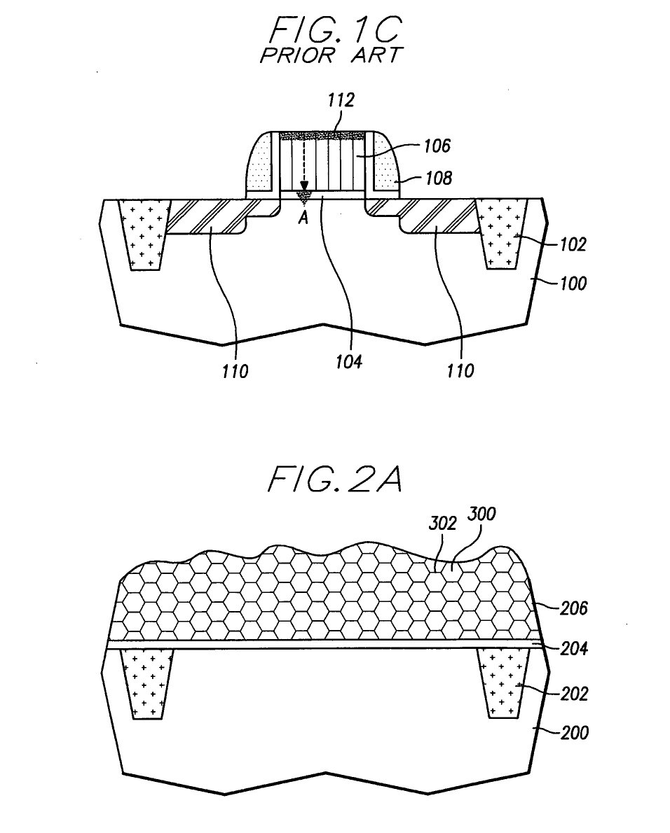

To clarify multiple layers and regions, the thickness of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

The detailed reaction and effect of the example disclosed methods for forming gate electrodes while preventing boron penetration to PMOS region may be understood by the following description.

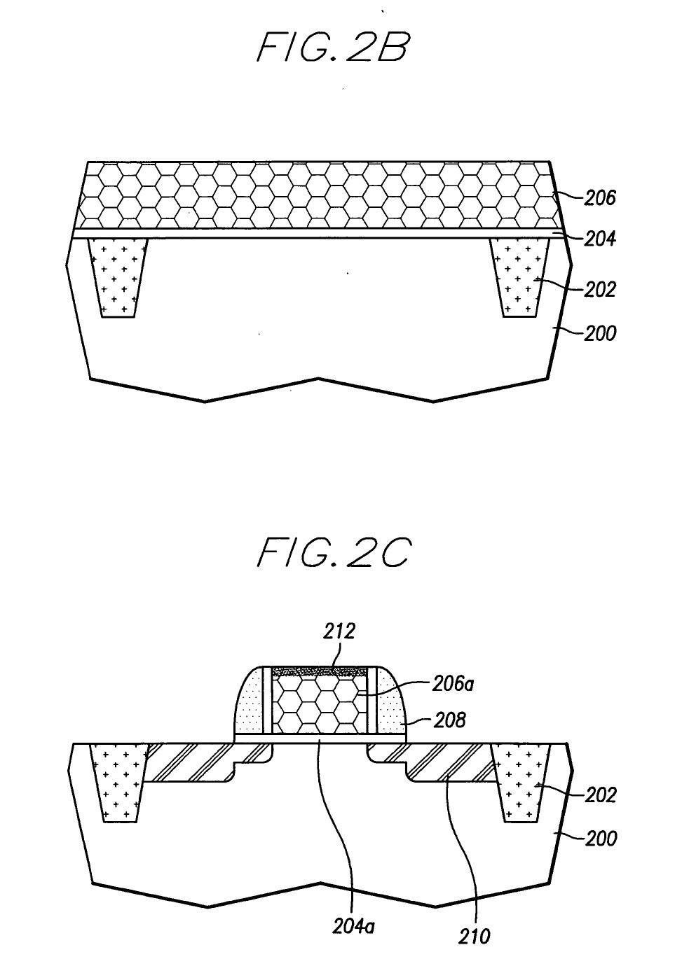

FIGS. 2a, 2b, and 2c are cross-sectional views for the method of forming the gate of semiconductor device.

Referring to FIG. 2a, a semiconductor substrate 200 is prepared. The substrate 200 may have an isolation layer 202 formed by, for example, Shallow Trench Isolation (STI) or Local Oxidation of Silicon (LOCOS) process. A gate oxide 204 is formed on the substrate 200 and polysilicon 206 having a rugged structure and for gate electrodes is deposited on the gate oxide 204. In one example, it may be desirable to deposit the polysilicon 206 by Chemical Vapor Deposition (CVD) with a precursor of silane (SiH₄) gas. In another example, SiH₂Cl₂ gas may be used as the precursor of the rugged polysilicon. In the deposition process for the rugged polysilicon 206, example conditions include the process temperature ranging from 550 to 580° C., the flow rate of silane ranging from 500 sccm to 1,500 sccm and chamber pressure from 50 Pa to 150 Pa. The polysilicon thus formed need not any post-processes for the formation of the rugged structure. In the conventional Dynamic Random Access Memory (DRAM) devices, the rugged structure of polysilicon layer is formed for the capacitor line. The conventional capacitor polysilicon requires vacuum annealing process for the formation of the rugged structure after the polysilicon or amorphous silicon layer is deposited. During the vacuum annealing post-process, the rugged structure is formed by the migration of the deposited polysilicon. However, as disclosed herein, the rugged polysilicon layer is directly formed by the deposition and does not require any post-process like the vacuum annealing.

The polysilicon formed under these conditions has a plurality of fine grains 300 and the grain boundaries 302 each of which forms an interface with the neighboring fine grains as shown in FIG. 2a. Further, the polysilicon 206 has a rugged structure having uneven surface.

Next, as shown in FIG. 2b, the surface of the polysilicon 206 is planarized by a CMP process. In one example, silica based alkali slurry and polyurethane pad are used under the pressure of 2 to 4 PSI. However, if the unevenness of the polysilicon 206 is within the permissible range, the planarization process may be omitted.

Referring to FIG. 2c, the gate oxide 204 and the polysilicon 206 are patterned to form a gate electrode 206a and spacers 206 are formed for the LDD structure. Then, source and drain regions 210 are formed by implanting boron (B⁺) or BF₂⁺ to the PMOS region and implanting P or As to the NMOS region, and an annealing process is carried out. In the formation of the source and drain regions 210, boron or BF₂⁺ ions are injected to a predetermined area 212 of the polysilicon 206 as well. However, the injected boron or BF₂⁺ ions cannot penetrate into the substrate 200 during the annealing process for the diffusion of implanted ions into the PMOS and NMOS regions, because of the plurality of grain boundaries 206a formed in the polysilicon gate 206a.

Methods of forming a gate in a semiconductor device, which can prevent a boron penetration during the annealing process, are disclosed herein. Additionally, the disclosed processes may improve the productivity and electrical characteristics of the semiconductor device.

According to one example, the process may include forming a gate electrode of rugged structure by deposition process. In one example, a method for forming a gate in a semiconductor device includes forming a gate oxide layer on a substrate having a region where a PMOS region and a NMOS region are formed; depositing a polysilicon of rugged structure on the gate oxide layer; planarizing the polysilicon by a CMP (Chemical Mechanical Polishing) process; and performing ions implantation to the PMOS and NMOS regions and then annealing process. The rugged structure of polysilicon may be formed by CVD process with a precursor of silane (SiH₄) or SiH₂Cl₂ gas and under conditions of the process temperature ranging from 550 to 580° C., the flow rate of silane ranging from 500 sccm to 1,500 sccm and chamber pressure from 50 Pa to 150 Pa. The polysilicon formed under these conditions may have a plurality of fine grains and the grain boundaries each of which forms an interface with the neighboring fine grains. The fine grain and grain boundaries of the rugged polysilicon can prevent the ions injected to the polysilicon during the ion implantation process from penetrating into the substrate during the annealing process.

Amorphous silicon does not have a grain and a grain boundary because of the lack of the stereospecificity of the atomic arrangement. Single crystal silicon has a grain and the atomic arrangement is stereospecific. While, the polysilicon has the plural grains. Depending on the shape of the grain, the crystal structure of the polysilicon is divided into two: the columnar structure; and the rugged structure, and boron ions may penetrate into the PMOS region along the grain boundary.

As disclosed herein, a polysilicon gate electrode of the rugged structure has fine grains by deposition process. Therefore, in one example, the process is capable of solving the problem for the boron penetration through the grain boundary. Further, the present invention performs CMP (Chemical Mechanical Polishing) process to smooth the stepped surface of the rugged polysilicon and ensure the uniform coverage of the next layer formed on the rugged polysilicon.

This patent application makes reference to, incorporates the same herein, and claims all benefits accruing under 35 U.S.C. §119 from an application for METHOD FOR FORMING GATE ELECTRODES IN SEMICONDUCTOR DEVICES filed in the Korean Industrial Property Office on Sep. 1, 2004, and there duly assigned Serial No. 10-2004-69512.

Although certain apparatus constructed in accordance with the teachings of the invention have been described herein, the scope of coverage of this patent is not limited thereto. On the contrary, this patent covers every apparatus, method and article of manufacture fairly falling within the scope of the appended claims either literally or under the doctrine of equivalents.

What is claimed is:

1. A method for forming a gate in a semiconductor device comprises:
forming a gate oxide layer on a substrate having a region where a PMOS region and a NMOS region are formed;
depositing a polysilicon of rugged structure on the gate oxide layer;
planarizing the polysilicon by a Chemical Mechanical Polishing (CMP) process; and
performing ions implantation to the PMOS and NMOS regions and then annealing process.

2. A method of claim 1, wherein the depositing a polysilicon is formed by Chemical Vapor Deposition (CVD) process that employs a precursor of silane (SiH₄) gas.

3. A method of claim 2, wherein the CVD process is performed at a temperature ranging from 550 to 580° C.

4. A method of claim 2, wherein a flow rate of the SiH₄ is 550 sccm to 1,500 sccm.

5. A method of claim 2, wherein the CVD process is performed with chamber pressure of 50 to 150 Pa.

6. A method of claim 1, wherein the depositing a polysilicon is formed by CVD process that employs a precursor of SiH₂Cl₂ gas.

7. A method of claim 1, wherein the CMP process is carried out by using silica based alkali slurry and polyurethane pad under the pressure of 2 to 4 PSI.
